(19) United States
(12) Patent Application Publication
(10) Pub. No.: US 2026/0165035 A1
(43) Pub. Date: Jun. 11, 2026

(54) SUPERCONDUCTING TUNABLE RESONATOR WITH WIDE TUNING RANGE UTILIZING RADIO FREQUENCY SUPERCONDUCTING QUANTUM INTERFERENCE DEVICES AND MULTI-STACKED CAPACITOR

(71) Applicant: Dell Products L.P., Round Rock, TX (US)

(72) Inventors: Navjot Kaur Khaira, Manotick (CA); Tejinder Singh, Manotick (CA)

(21) Appl. No.: 18/961,071

(22) Filed: Nov. 26, 2024

(51) Int. Cl. H10N 60/12; G01R 33/035; G06N 10/40; H03J 3/20; H10N 60/80; H10N 60/82; H10N 60/83

(52) U.S. Cl. CPC H10N 60/12; G01R 33/0354; H03J 3/20; H10N 60/805; H10N 60/82; H10N 60/83; G06N 10/40

(57) ABSTRACT

The technology described herein is directed towards a tunable superconducting resonator with a relatively wide tuning range based on radio-frequency superconducting quantum interference devices (rf-SQUIDs). In one example implementation, the technology includes a multi-stacked capacitor, facilitating a large value capacitor using multi-layer superconducting thin films for an ultra-compact footprint. In one example design, a group of rf-SQUIDs are aligned between a transmission line/inductor in the resonator and a control line. When a small current is applied to the control line, the rf-SQUIDs' inductance, and consequently the resonator's total inductance, varies, whereby tuning the inductance is equivalent to tuning the resonant frequency for the resonator. In this way, a wideband tuning mechanism in a superconducting resonator is achieved using a relatively small, practical number of rf-SQUIDs and a straightforward application of controlled direct current. Also described are E-H shielding poles that help shield excess magnetic flux from nearby components.

The subject patent application is related to U.S. patent application Ser. No. ______, filed ______, and entitled “QUANTUM MEMORY CELL USING BROADBAND SUPERCONDUCTING TUNABLE RESONATOR” (docket no. 140730.01/DELLP1361US), U.S. patent application Ser. No. ______, filed ______, and entitled “SENSE-TAP DEVICE FOR QUBIT COHERENCE VERIFICATION AND ERROR DETECTION IN QUANTUM MEMORIES” (docket no. 140731.01/DELLP1360US), U.S. patent application Ser. No. ______, filed ______, and entitled “MONOLITHIC INTEGRATED QUANTUM MEMORY DEVICE ARRAY WITH MULTI-LAYER SUPERCONDUCTING STACK” (docket no. 140732.01/DELLP1362US), U.S. patent application Ser. No. ______, filed ______, and entitled “MULTI-BIT QUANTUM MEMORY CELL WITH INTEGRATED HIGH QUALITY FACTOR STORAGE RESONATORS” (docket no. 140733.01/DELLP1359US), the respective entireties of which patent applications are hereby incorporated by reference herein.

### BACKGROUND

Superconducting tunable microwave resonators are used in various technologies, such as microwave tunable filters, tunable couplers, tunable parametric amplifiers, superconducting quantum interference devices (SQUID) multiplexers, astrophysical detectors, and scanning microwave microscopes. Superconducting resonators are used with various quantum technologies, such as in the readout and control of qubits in quantum computing; that is, for qubit readout, capture, storage, on-demand release, and routing of microwave photons.

However, traditional superconducting resonator designs are limited in terms of tunability, compactness, and ease of integration. Some challenges with such existing superconducting resonators include limited tuning range, footprint constraints, integration and fabrication complexity, and scalability.

### BRIEF DESCRIPTION OF THE DRAWINGS

The technology described herein is illustrated by way of example and not limited to the accompanying figures in which like reference numerals indicate similar elements and in which:

FIG. 1 is a top-view representation of an example superconducting tunable resonator device, in accordance with various example embodiments and implementations of the subject disclosure.

FIG. 2 is a three-dimensional (3D) view of a zoomed-in portion of the example superconducting tunable resonator device of FIG. 1, highlighting an array of radio frequency-superconducting quantum interference devices (rf-SQUIDs), in accordance with various example embodiments and implementations of the subject disclosure.

FIG. 3 is a top-view representation, corresponding to FIG. 1, highlighting example components and regions of the superconducting tunable resonator device, in accordance with various example embodiments and implementations of the subject disclosure.

FIG. 4 is an enlarged 3D-view representation showing details of an example rf-SQUID, in accordance with various example embodiments and implementations of the subject disclosure.

FIG. 5 is a sideview representation showing a multilayer stack used in an example superconducting device implementation, in accordance with various example embodiments and implementations of the subject disclosure.

FIG. 6 is a 3D-view representation showing a multilayer stack used in an example superconducting device implementation, in accordance with various example embodiments and implementations of the subject disclosure.

FIG. 7 is an enlarged 3D-view representation showing an example multi-stacked capacitor with two sets of electrodes designed using superconducting thin films, in accordance with various example embodiments and implementations of the subject disclosure.

FIG. 8 is a graphical representation showing example magnitude response of a tunable superconducting resonator as described herein, demonstrating a relatively large tuning range varied via a control current, in accordance with various example embodiments and implementations of the subject disclosure.

FIG. 9 is a graphical representation showing example phase response of a tunable superconducting resonator as described herein, demonstrating a relatively large tuning range varied via a control current, in accordance with various example embodiments and implementations of the subject disclosure.

FIG. 10 is a surface plot for a tunable superconducting resonator as described herein, demonstrating frequency shift with a change in control current and magnitude response variation, in accordance with various example embodiments and implementations of the subject disclosure.

FIG. 11 is a flow diagram showing example operations related to controlling a superconducting tunable resonator device to resonate at a selected resonance frequency, including applying a controlled amount of direct current that determines an inductance of rf-SQUIDs, in accordance with various example embodiments and implementations of the subject disclosure.

### DETAILED DESCRIPTION

The technology described herein is generally directed towards a superconducting resonator with a relatively wide tuning range based on radio-frequency superconducting quantum interference devices (rf-SQUIDs). In one example embodiment, the technology includes a large value capacitor implementation using multi-layer superconducting thin films for an ultra-compact footprint, which is configured as a multi-stacked capacitor design utilizing superconducting thin films to reduce the area of the chip. The resulting technology facilitates a superconducting tunable resonator device, which utilizes rf-SQUIDs and the multi-layer stacked capacitor, for a wide tuning range and ultra-compact footprint.

In one example implementation, a group of (e.g., four) rf-SQUIDs are aligned along with an inductor in the resonator. When a small current is applied on a control line proximate to the rf-SQUIDs, the rf-SQUIDs' inductance, and consequently the resonator's total inductance, varies, whereby tuning the inductance is equivalent to tuning the resonant frequency for the resonator. The on-chip current in the control line running close to the rf-SQUIDs provides a changing magnetic field to the rf-SQUIDs. In this way, a wideband tuning mechanism in a superconducting resonator is achieved using a relatively small, practical number of (e.g. four) rf-SQUIDs and a straightforward application of controlled direct current.

Further, the design described herein helps to avoid any cross-magnetic coupling with qubits, based on the intermixing of DC current via an independent control current line inductively coupled to the rf-SQUIDs. The independent control current line helps to ensure that the external control current does not impact the mutual coupling of the rf-SQUIDs with the transmission line. Still further, E-H shielding is created in one implementation by cross-connecting the superconducting interconnects (poles) from the top to the bottom superconducting thin films, to isolate any excess magnetic flux from nearby similar superconducting devices (e.g., resonators/cells). This is significant when dealing with high-density memory elements where magnetic flux-coupled cells are fabricated in close proximity.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

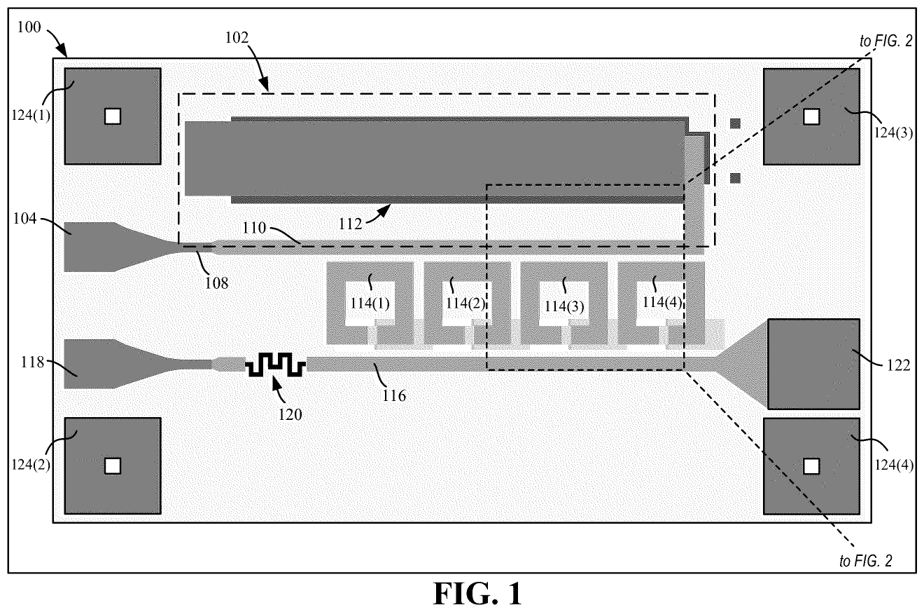

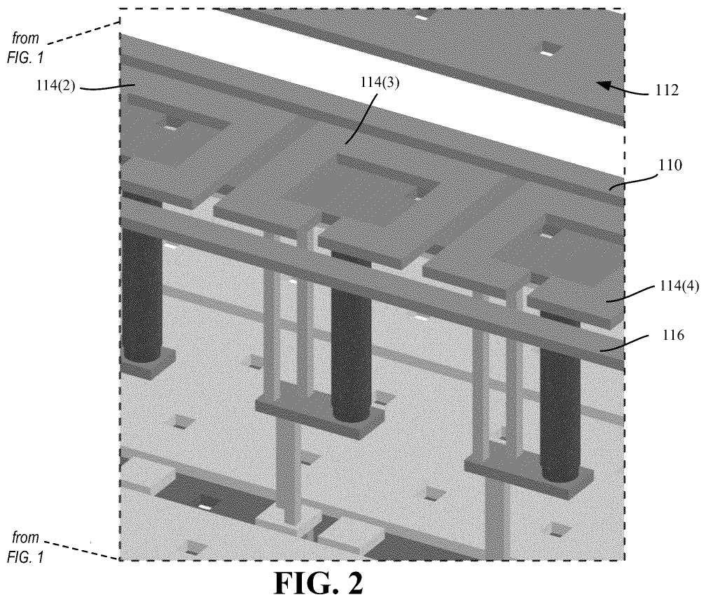

FIG. 1, along with an enlarged portion thereof in FIG. 2, show a layout and a chip design (device) 100 of one example superconducting resonator 102 as described herein. The device 100 includes a signal input port 106 connected by a superconducting microstrip transmission line 108 to a superconducting inductor 110. A multi-stacked metal-insulator-metal (MIM) capacitor 112 having capacitance (C) and the superconducting inductor 110 with inductance (L) are connected in series with the transmission line section 108 connected with the signal input port 104.

In one implementation, the superconducting inductor 110 and the MIM capacitor 112 are sized to tune the resonance frequency within the frequency band 4 GHz to 8 GHz, which is one of the most popular for the quantum systems. The tunable inductor 110 is implemented using a transmission line loaded with an array of (e.g., four) rf-SQUIDs 114(1)-114(4), and is terminated in a short circuit.

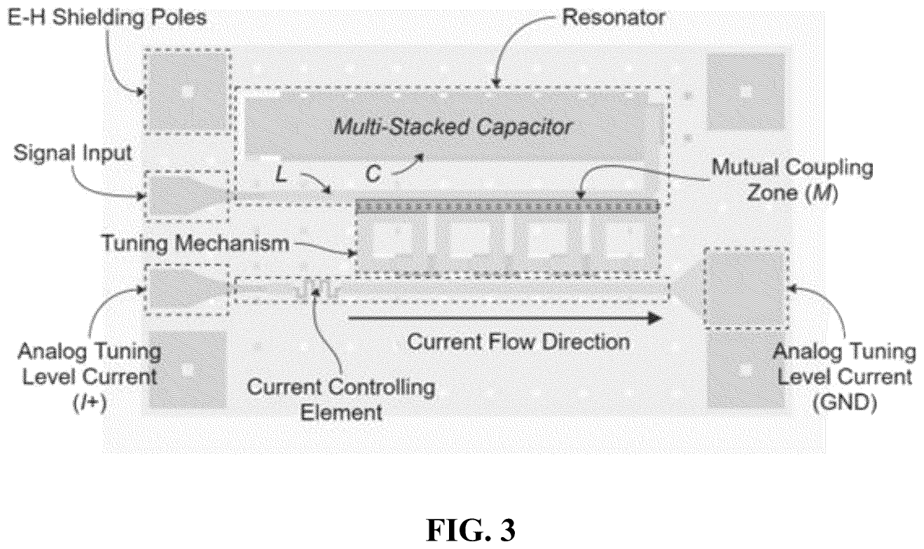

An isolated control wire 116 for an analog tuning level current (I+) carrying a DC-current is placed adjacent to the array of rf-SQUIDs 114(1)-114(4) to tune their inductance as described herein. The controlled current is input at port 118 and flows through a current controlling element (e.g., meandering resistor) 120, terminating at ground (block 122). Four E-H shielding poles 124(1)-124(4), one per corner in the example implementation of FIG. 1, help isolate any excess magnetic flux from nearby components, e.g., additional resonators. Note that FIG. 2, as well as FIGS. 3, 4, 6 and 7, show perforations in some of the layers, which are for manufacturing purposes and do not significantly impact RF performance.

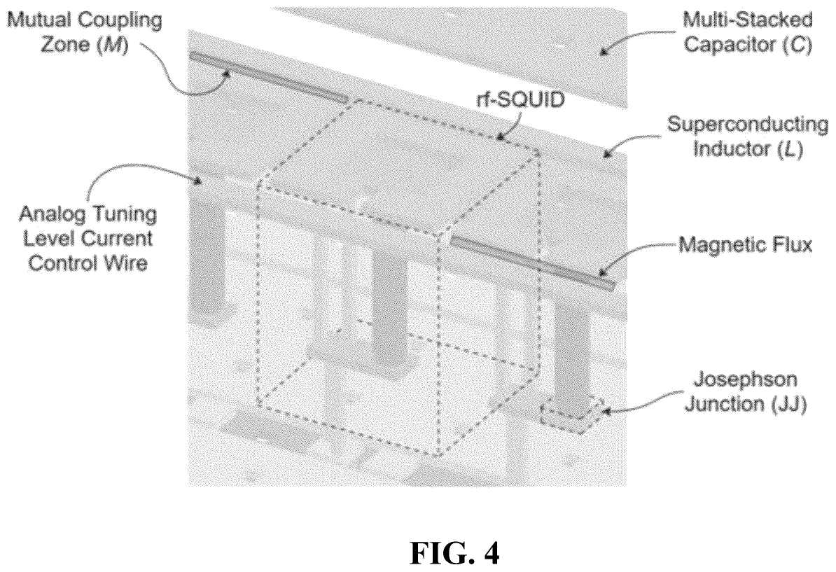

FIGS. 3 and 4 are similar to FIGS. 1 and 2, respectively, noting that a mutual coupling zone (M) is specifically identified in FIGS. 3 and 4. FIG. 4 also depicts a region of magnetic flux, and a Josephson junction (JJ) of an adjacent rf-SQUID. More particularly, each rf-SQUID has one Josephson junction shunted by an inductive superconductive loop, in which a Josephson junction is a fundamental component in superconducting quantum circuits, made from two superconductors separated by a thin insulating barrier. When a current flows through the junction, the current can tunnel through the insulator without any voltage drop, a phenomenon known as the Josephson effect. An rf-SQUID combines the physical phenomenon of flux quantization and Josephson tunneling.

Through mutual coupling, the tunable inductance of the rf-SQUIDs tunes the effective inductance of the microstrip transmission line as highlighted in FIGS. 3 and 4. The mutual coupling zone (M) thus establishes the resonance frequency of the resonator tunable. Note that rf-SQUID inductance can be tuned by an externally applied magnetic field using the DC-current carrying transmission line as described herein, or by varying the input RF power.

Example design parameters of the presented resonator are given in Table 1 below. Note that another variation of the resonator design using a single RF port can also be made by placing both the inductor and capacitor elements in shunt instead of series.

TABLE 1
Design specifications of an example tunable resonator:

| Design parameter | Value |
|---|---|
| Width of the STF microstrip inductor | 2 μm |
| Area of each plate of the capacitor | 10 μm × 80 μm |
| Area of each SQUID loop | 12 μm × 14 μm |
| Number of total rf-SQUIDs | 4 |
| Diameter of JJ | 2 μm |
| Gap between rf-SQUIDs and inductor | 1 μm |
| Gap between adjacent rf-SQUIDs | 1.1 μm |
| Width of the Tuning control wire | 2 μm |

The superconducting inductor 110 with inductance (L) can be designed by placing the top conductor and the ground plane on two different superconducting thin film (STF) layers spaced with layers of dielectric to achieve a characteristic impedance Z₀=50 Ohm. Each rf-SQUID used in the design is a superconducting loop made by an STF and shunted by a single JJ. The superconducting loop can be designed on the same microstrip signal STF layer in the form a ring, or alternatively, the rf-SQUIDs can be placed between the top conductor of the microstrip and the ground plane using two additional STF layers.

To summarize, the superconducting inductor 110 (L) is connected with a capacitor 112 which is shunted to the ground. The array of four rf-SQUIDs 114(1)-114(4) is laid out along the length of the superconducting inductor 110. Note however, that in one alternative implementation, the analog tuning level current can be applied to the superconducting inductor 110 through the signal port (e.g., 104, FIG. 1) and through bias tees directly. In that case, the control current cannot be exceeded beyond the threshold critical current of the superconductor material, otherwise the superconductor material switches to its non-superconducting state and the device performance suffers significantly, along with a high probability of the qubit collapsing and creating standing waves on the superconducting wires, and increasing thermal noise.

Thus, in one implementation of the device, the independent analog tuning level current control wire 116, which runs parallel to the rf-SQUIDs 114(1)-114(4) is used. The control wire 116 is coupled to the input port 118 and the terminated by ground (block 122), which are DC contacts (e.g., pads) on each end to provide the control current. Because this is a superconducting circuit, to limit the current, the current controlled element 120 is included as a control current resistor (CCR) using a lossy material.

The amount of DC current provided to the control line 116 determines the flux coupled to the rf-SQUID inductance loops, which changes the dynamic inductance of the rf-SQUID. The rf-SQUIDs act as variable inductors, and because they are magnetically coupled to the inductor 116 via the superconducting inductor section, the change in rf-SQUID inductance causes change in the resonator inductance and hence the resonance frequency.

More particularly, when an external control current Iₑₓₜ is provided to the tuning control wire 116 with inductance L_{c}, a magnetic field is generated, which produces an external magnetic flux φₑₓₜ (or fₑₓₜ) given by:

$${ϕ}_{ext} = {L}_{c} {I}_{ext} .$$

When the SQUID loop with a self-inductance Lₛ is threaded by the external flux φₑₓₜ (or fₑₓₜ), due to flux quantization condition, a circulating current iₛ is induced in order to screen this flux. The flux due to the circulating current also adds to the total flux φₛ (or fₛ, which is expressed as:

$${ϕ}_{s} = {ϕ}_{ext} + {L}_{s} {i}_{s} .$$

The amount of circulating supercurrent is determined as:

$${i}_{s} = - {I}_{c} sin ( \frac{2 {πϕ}_{s}}{{ϕ}_{0}} )$$

where I_{c} is the critical current of the JJ and φ=2.0679×10⁻¹⁵ is the magnetic flux quantum.

The superconducting loop inductance Lₛ is coupled to the superconducting inductor 110 (Lᵣ) with mutual inductance M. The value of mutual inductance M depends on the gap between the rf-SQUID and the microstrip transmission line. The coupling coefficient K and the screening parameter β of an rf-SQUID are given by:

$${K}^{2} = \frac{{M}^{2}}{{L}_{r} {L}_{s}} ,$$

$$β = \frac{2 π {L}_{s} {L}_{c}}{{ϕ}_{0}} .$$

The inductance is then varied by the magnetic field generated by the DC current carrying wire 116 placed on the side. The effective inductance of the microstrip line is then given as:

$${L}_{r}^{′} = {L}_{r} ( 1 - Δ L )$$

where ΔL is given by:

$$Δ L = \frac{{K}^{2}}{1 + 1 / β cos ( 2 {πϕ}_{s} / {ϕ}_{0} )} .$$

As C is the capacitance of the multi-stacked MIM capacitor 112, in the absence of control current, the resonance frequency is given by fᵣ=½π\sqrt{LC}. Providing a control current changes the variable inductance of transmission line, and the resonance frequency changes by

$${f}_{r}^{′} = 1 / 2 π \sqrt{{L}^{′} C} .$$

Using the array of rf-SQUIDs 114(1)-114(4) and a high critical current JJs allows obtaining a wider tunability range. Notwithstanding, any practical number of one or more rf-SQUIDs can be used in a given implementation, depending on how much inductance change each rf-SQUID provides, such as if the manufacturing process allows high current density of the Josephson junction; (there is a tradeoff, as having too much current on the line to use fewer rf-SQUIDs can cause issues, while having more rf-SQUIDs enlarges the device footprint).

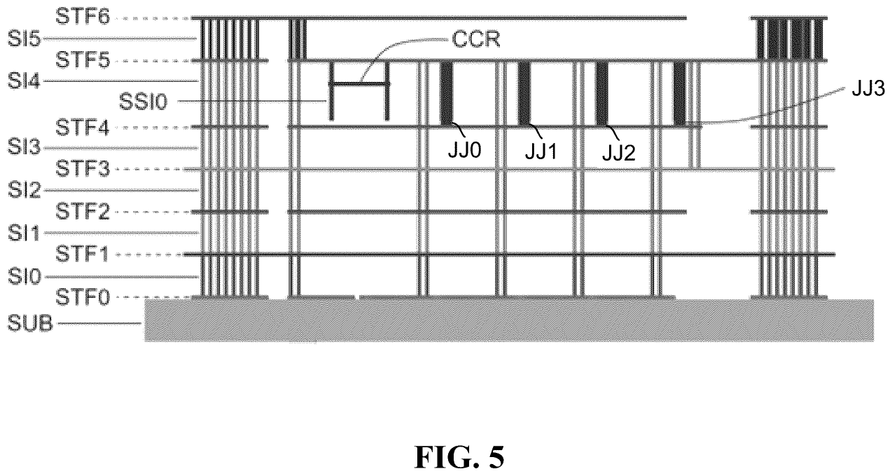

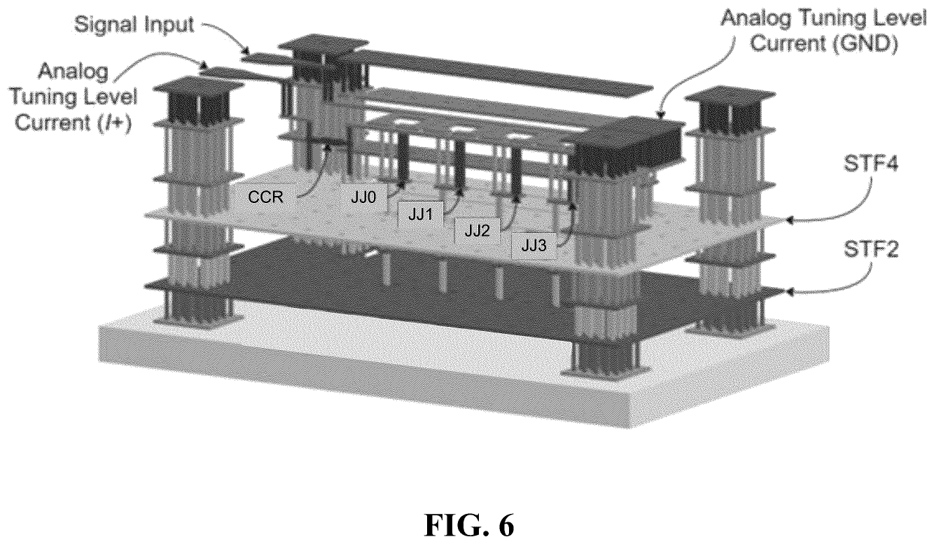

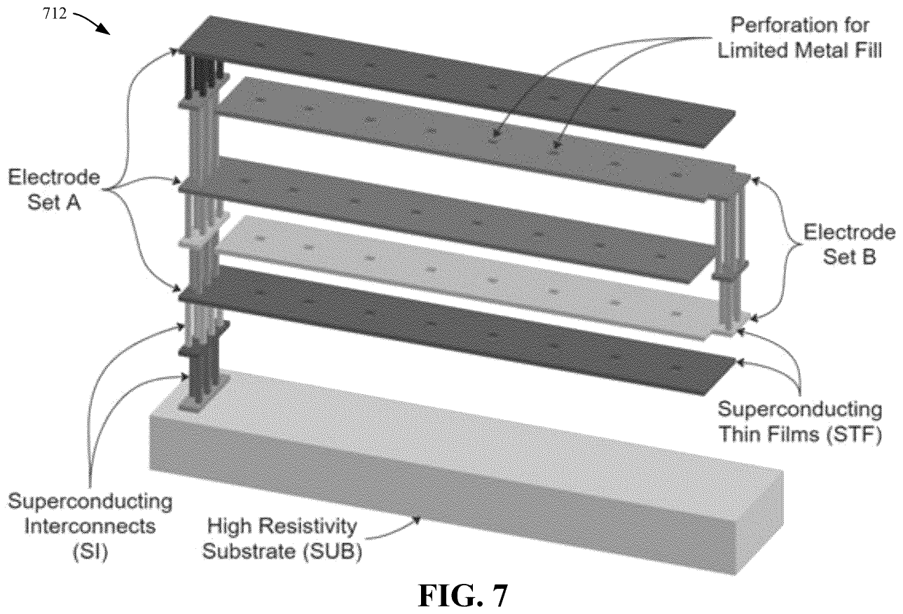

Turning to fabrication of an example superconducting resonator device, FIG. 5 shows a fabrication stack cross-section, which includes multiple superconducting thin films (STF0-STF6) above a substrate (SUB) connected using superconducting interconnects (SI0-SI5). FIG. 6 shows a 3D view of an example superconducting device implementation (with layer height Z-scaled). Also shown in FIGS. 5 and 6 is a short SI (SSI0), current controlling resistor layer (CCR) and Josephson Junctions (JJ0-JJ3). In one implementation, the capacitor (FIG. 7) is a MIM capacitor, which offers higher capacitance density and higher self-resonance compared to an interdigitated capacitor design, for example.

More particularly, in the example of FIG. 7, a MIM multi-stack capacitor is shown in a 3D view, and includes (e.g., five) STF layers and (e.g., four) dielectric layers between the STF layers (not explicitly depicted so as to view the metallic STF layers), effectively realizing four capacitors connected in parallel. A higher capacitance using a smaller area is achieved using this design technique. More particularly, one implementation of the design uses a stack of five STF 10 μm×80 μm rectangular sections separated by four ˜100 nm dielectric layers. The capacitance value offered by the stack can be closely estimated by means of electromagnetic EM simulations. The overall capacitor area can be further reduced and the value of achieved capacitance can be increased by increasing the number of stacked metal layers as per the process stack.

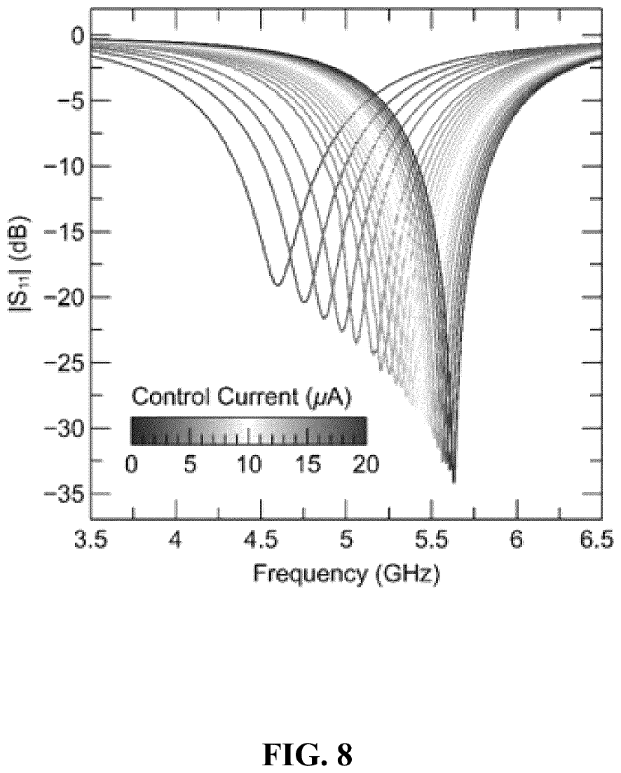

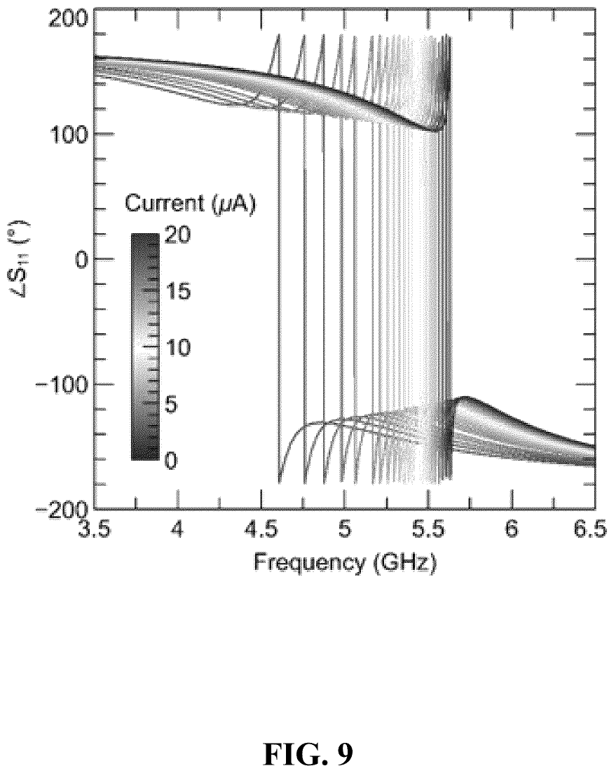

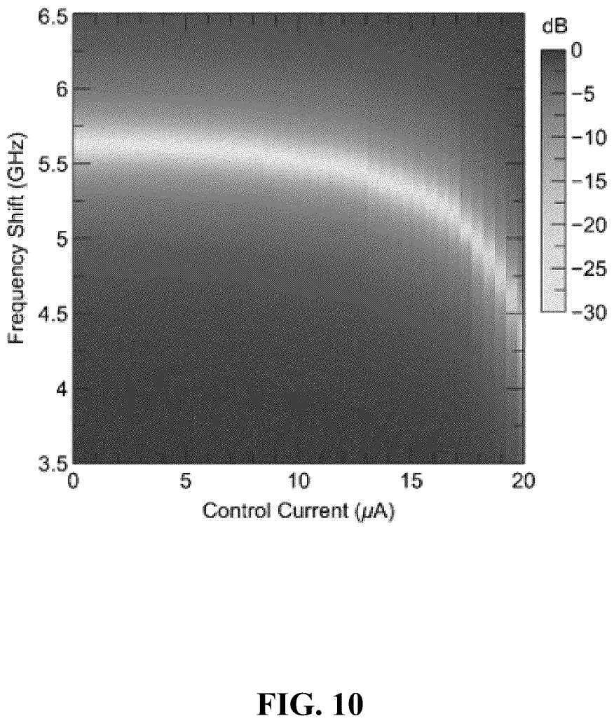

With respect to simulation, a superconducting resonator device (e.g., 102, FIG. 1) can be designed and simulated in 3D electromagnetic solver, and multiple variations simulated over a control current range of 0 to 20 μA. FIG. 8 shows the S₁₁ magnitude response of one such tunable resonator, highlighting a large tuning range, achieved with only four rf-SQUIDs. FIG. 9 shows the respective phase response in degrees (°) of the tunable superconducting resonator. A surface plot visualization highlighted in FIG. 10 shows the change in frequency shift with an application of control current and the respective variation of the magnitude response.

One or more implementations and embodiments can be embodied in a system, such as described and represented in the example herein. The system can include a superconducting tunable resonator device associated with a qubit via a signal input port. The superconducting tunable resonator device can include a superconducting transmission line coupled to a superconducting inductor and a resonator, one or more rf-SQUIDs inductively coupled to the superconducting transmission line, and a tuning circuit comprising a control wire inductively coupled to the one or more rf-SQUIDs. Amount of control current carried by the control wire determines an inductance of the one or more rf-SQUIDs to change a resonant frequency of the superconducting tunable resonator device.

The one or more rf-SQUIDs can include an array of rf-SQUIDs aligned along the superconducting transmission line.

The one or more rf-SQUIDs can include an array of four rf-SQUIDs aligned along the superconducting transmission line.

The control wire can be separate from the superconducting transmission line.

The one or more rf-SQUIDs can include an array of rf-SQUIDs aligned between the superconducting transmission line and the control wire.

The control wire can be coupled to an analog tuning input contact via a current controlling resistive element positioned between the analog tuning input contact and the control wire.

The control wire can include the signal line.

The capacitor can include a multi-stacked capacitor comprising a stack of conductive plates insulated from one another via a dielectric.

The system further can include at least one shielding pole.

The control current can include direct current.

The direct current can be less than thirty microamperes.

The resonance frequency of the superconducting tunable resonator device can be tunable, based on the control current, within a frequency band ranging from approximately four gigahertz to approximately eight gigahertz.

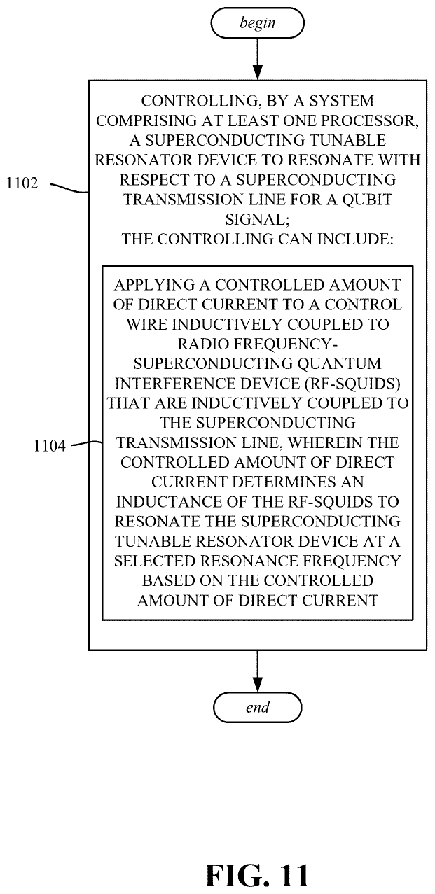

One or more example implementations and embodiments, such as corresponding to example operations of a method, are represented in FIG. 11. Example operation 1102 represents controlling, by a system comprising at least one processor, a superconducting tunable resonator device to resonate with respect to a superconducting transmission line for a qubit signal; the controlling can include example operation 1104. Example operation 1104 represents applying a controlled amount of direct current to a control wire inductively coupled to rf-SQUIDs that can be inductively coupled to the superconducting transmission line, wherein the controlled amount of direct current determines an inductance of the rf-SQUIDs to resonate the superconducting tunable resonator device at a selected resonance frequency based on the controlled amount of direct current.

Further operations can include selecting, by the system, the controlled amount of direct current to resonate the superconducting tunable resonator device at the selected resonance frequency.

The selected resonance frequency can be a first selected resonance frequency, and further operations can include changing, by the system, the controlled amount of direct current from a first controlled amount of direct current corresponding to the first selected resonance frequency, to a second of controlled amount of direct current to resonate the superconducting tunable resonator device at a second resonance frequency that can be different from the first resonance frequency.

One or more implementations and embodiments can be embodied in a superconducting device, such as described and represented in the examples herein. The superconducting device can include a superconducting transmission line coupled to a signal input port, a superconducting inductor, and a resonator. The superconducting device can include a tuning device that tunes a resonant frequency of the superconducting device. The tuning device can include a group of radio frequency-superconducting quantum interference devices (rf-SQUIDs) inductively coupled to the superconducting transmission line, and a control wire inductively coupled to the rf-SQUIDS, the control wire coupled via a resistive element to an analog tuning port. A direct current applied at the analog tuning port can flow through the control wire as a control current that determines an inductance of the group of rf-SQUIDs to tune the resonant frequency.

The capacitor can include a multi-stacked capacitor.

The superconducting device can include shielding poles configured to magnetically shield the superconducting transmission line and the tuning device from one or more other superconducting devices proximate to the superconducting device.

The group of radio frequency-superconducting quantum interference devices can be aligned parallel or substantially parallel between the superconducting transmission line and the control wire.

The superconducting transmission line can be associated with a qubit, and used for at least one of: qubit readout, qubit capture, qubit storage, on-demand qubit release, or routing of single microwave photons of the qubit.

As can be seen, the technology described herein facilitates a tunable superconducting resonator device based on rf-SQUIDs and a multi-layer stacked capacitor for a wide tuning range and ultra-compact footprint. This enhances the performance and scalability of quantum hardware while simplifying the integration process.

For example, in one usage scenario, quantum hardware (e.g., with fifty or more) superconducting qubits takes the form of a quantum network with superconducting coplanar waveguide (CPW) resonators (bus couplers or readout resonators) providing paths for microwave photons to indirectly interact with processing qubit nodes. In such a scheme, a resonator is used to exchange a photon with its adjacent qubits for readout or entanglement operations. Superconducting resonators are typically easier to fabricate and optimize their characteristics compared to qubits where there are many more complex factors. Superconducting resonators are thus an integral part of the qubit system as well as memory for quantum information. The superconducting tunable resonator technology described herein thus addresses existing issues, including with respect to tuning range, footprint constraints, integration and fabrication complexity, and scalability.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A system, comprising:
a superconducting tunable resonator device associated with a qubit via a signal input port, the superconducting tunable resonator device comprising:
a superconducting transmission line coupled to a superconducting inductor and a resonator,
one or more radio frequency-superconducting quantum interference devices (rf-SQUIDs) inductively coupled to the superconducting transmission line, and
a tuning circuit comprising a control wire inductively coupled to the one or more rf-SQUIDs, wherein an amount of control current carried by the control wire determines an inductance of the one or more rf-SQUIDs to change a resonant frequency of the superconducting tunable resonator device.

2. The system of claim 1, wherein the one or more rf-SQUIDs comprise an array of rf-SQUIDs aligned along the superconducting transmission line.

3. The system of claim 1, wherein the one or more rf-SQUIDs comprise an array of four rf-SQUIDs aligned along the superconducting transmission line.

4. The system of claim 1, wherein the control wire is separate from the superconducting transmission line.

5. The system of claim 4, wherein the one or more rf-SQUIDs comprise an array of rf-SQUIDs aligned between the superconducting transmission line and the control wire.

6. The system of claim 4, wherein the control wire is coupled to an analog tuning input contact via a current controlling resistive element positioned between the analog tuning input contact and the control wire.

7. The system of claim 1, wherein the control wire comprises the signal line.

8. The system of claim 1, wherein the capacitor comprises a multi-stacked capacitor comprising a stack of conductive plates insulated from one another via a dielectric.

9. The system of claim 1, further comprising at least one shielding pole.

10. The system of claim 1, wherein the control current comprises direct current.

11. The system of claim 10, wherein the direct current is less than thirty microamperes.

12. The system of claim 10, wherein the resonance frequency of the superconducting tunable resonator device is tunable, based on the control current, within a frequency band ranging from approximately four gigahertz to approximately eight gigahertz.

13. A method, comprising:
controlling, by a system comprising at least one processor, a superconducting tunable resonator device to resonate with respect to a superconducting transmission line for a qubit signal, the controlling comprising:
applying a controlled amount of direct current to a control wire inductively coupled to radio frequency-superconducting quantum interference devices (rf-SQUIDs) that are inductively coupled to the superconducting transmission line, wherein the controlled amount of direct current determines an inductance of the rf-SQUIDs to resonate the superconducting tunable resonator device at a selected resonance frequency based on the controlled amount of direct current.

14. The method of claim 13, further comprising selecting, by the system, the controlled amount of direct current to resonate the superconducting tunable resonator device at the selected resonance frequency.

15. The method of claim 13, wherein the selected resonance frequency is a first selected resonance frequency, and further comprising changing, by the system, the controlled amount of direct current from a first controlled amount of direct current corresponding to the first selected resonance frequency, to a second of controlled amount of direct current to resonate the superconducting tunable resonator device at a second resonance frequency that is different from the first resonance frequency.

16. A superconducting device, comprising:
a superconducting transmission line coupled to a signal input port, a superconducting inductor, and a resonator; and
a tuning device that tunes a resonant frequency of the superconducting device, the tuning device comprising:
a group of radio frequency-superconducting quantum interference devices (rf-SQUIDs) inductively coupled to the superconducting transmission line; and
a control wire inductively coupled to the rf-SQUIDS, the control wire coupled via a resistive element to an analog tuning port,
wherein a direct current applied at the analog tuning port flows through the control wire as a control current that determines an inductance of the group of rf-SQUIDs to tune the resonant frequency.

17. The superconducting device of claim 16, wherein the capacitor comprises a multi-stacked capacitor.

18. The superconducting device of claim 16, comprising shielding poles configured to magnetically shield the superconducting transmission line and the tuning device from one or more other superconducting devices proximate to the superconducting device.

19. The superconducting device of claim 16, wherein the group of radio frequency-superconducting quantum interference devices is aligned parallel or substantially parallel between the superconducting transmission line and the control wire.

20. The superconducting device of claim 16, wherein the superconducting transmission line is associated with a qubit, and used for at least one of: qubit readout, qubit capture, qubit storage, on-demand qubit release, or routing of single microwave photons of the qubit.
